(19) United States
(12) Patent Application Publication
(10) Pub. No.: US 2025/0301887 A1
(43) Pub. Date: Sep. 25, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-Si (KR)

(72) Inventor: JOOHYEON LEE, Yongin-si (KR)

(21) Appl. No.: 19/012,858

(22) Filed: Jan. 8, 2025

(30) Foreign Application Priority Data
Mar. 19, 2024 (KR) 10-2024-0037631

(51) Int. Cl. H10K 59/80; H10K 59/12; H10K 102/00

(52) U.S. Cl. CPC H10K 59/873; H10K 59/1201; H10K 2102/311

(57) ABSTRACT

A display device includes a display panel, a first polymer disposed on the display panel, in direct contact with the display panel, and having a first modulus, a second polymer disposed on the first polymer, in direct contact with the first polymer, and having a second modulus less than the first modulus, and a window layer disposed on the second polymer.

### CROSS-REFERENCE TO RELATED APPLICATION

This application claims priority to Korean Patent Application No. 10-2024-0037631, filed on Mar. 19, 2024, and all the benefits accruing therefrom under 35 U.S.C. § 119, the content of which in its entirety is herein incorporated by reference.

### BACKGROUND

### 1. Field

A present disclosure relates to a display device, a method of manufacturing the display device, and an electronic device including the display device. More specifically, the present disclosure relates to a display device that provides visual information, the method of manufacturing the display device, and the electronic device including the display device.

### 2. Discussion of the Background

Flexible display devices may have advantages in space utilization, interior design, and design, and have a variety of application fields. Recently, these flexible display devices may be divided into bendable, rollable, foldable, etc., and recently there is a demand for transformation into a stretchable form stretched in random directions.

A flexible display device formed using a substrate having such flexibility has limitations in folding as a thickness increases. In addition, it has been found that wrinkles are formed due to bending during folding, and various studies are continuing to solve these problems.

### SUMMARY

One feature of the present disclosure is to provide a display device with improved stability and reliability.

Another feature of the present disclosure is to provide a method of manufacturing the display device.

A display device according to an embodiment of the present disclosure includes a display panel, a first polymer disposed on the display panel, in direct contact with the display panel, and having a first modulus, a second polymer disposed on the first polymer, in direct contact with the first polymer, and having a second modulus less than the first modulus, and a window layer disposed on the second polymer.

In an embodiment, the first modulus may be about 500 MPa or more and about 2000 MPa or less.

In an embodiment, the second modulus may be about 30 MPa or less.

In an embodiment, a thickness of each of the first polymer and the second polymer may be about 30 μm or more and about 70 μm or less.

In an embodiment, a sum of a thicknesses of the first polymer and the second polymer may be about 100 μm or less.

In an embodiment, an adhesive force of the first polymer may be greater than an adhesive force of the second polymer.

In an embodiment, an adhesive force between the first polymer and the display panel may be about 1500 gf/inch or more.

In an embodiment, an elastic recovery rate of the second polymer may be about 90% or more.

In an embodiment, a creep value of the second polymer for about 1 hour may be about 10% or less.

In an embodiment, the first polymer and the second polymer may be transparent.

In an embodiment, the display device may further include a third polymer disposed on the second polymer and covering at least a portion of the second polymer, and the second polymer may have a shape including a plurality of protrusions protruding in a direction of the window layer in a cross-sectional view.

In an embodiment, the protrusions of the second polymer may be in direct contact with the window layer.

In an embodiment, the first polymer and the third polymer may include a same material.

In an embodiment, a thickness of each of the protrusions of the second polymer may be about 15 μm or more and about 20 μm or less.

In an embodiment, the protrusions of the second polymer may have a constant pitch, and

the pitch may be about 10 μm or more and about 50 μm or less.

A method of manufacturing a display device according to an embodiment of the present disclosure includes providing a display panel, forming a first polymer having a first modulus on the display panel, forming a second polymer having a second modulus less than the first modulus on the first polymer, and forming a window layer on the second polymer.

In an embodiment, the method may further include forming a protrusion pattern including a plurality of protrusions in the second polymer.

In an embodiment, the method may further include forming a third polymer covering at least a portion of the second polymer on the second polymer.

In an embodiment, a thickness of each of the protrusions of the second polymer may be about 15 μm or more and about 20 μm or less.

In an embodiment, the protrusions of the second polymer may have a constant pitch, and the pitch may be about 10 μm or more and about 50 μm or less.

An electronic device according to an embodiment of the present disclosure includes a display device and a processor that drives the display device. The display device includes a display panel, a first polymer disposed on the display panel, in direct contact with the display panel, and having a first modulus, a second polymer disposed on the first polymer, in direct contact with the first polymer, and having a second modulus less than the first modulus, and a window layer disposed on the second polymer.

The display device may include a display panel, a first polymer disposed on the display panel, in direct contact with the display panel, and having a first modulus, a second polymer disposed on the first polymer, in direct contact with the first polymer, and having a second modulus less than the first modulus, and a window layer disposed on the second polymer.

As a result, the polymer layer, which includes polymers having different moduli and is formed of a plurality of layers, is disposed on the display device, thereby improving the adhesive force between the polymer layer and the window and the display panel. Additionally, impacts applied to the display device may be effectively absorbed and/or dispersed by the polymer layer.

In addition, by disposing a polymer layer having a plurality of layers, a damping layer and the adhesive for attaching it may be omitted, and an overall thickness of the display device may be reduced. That is, the damping layer and the adhesive process for attaching it may be omitted, thereby reducing a processing cost of the display device.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a plan view of a display device according to an embodiment of the present disclosure.

FIG. 2 is a cross-sectional view showing a folded state of the display device shown in FIG. 1.

FIG. 3 is a cross-sectional view taken along line I-I′ of FIG. 1.

FIG. 4 is a cross-sectional view showing the display panel of FIG. 3.

FIG. 5 is a cross-sectional view showing an example of the polymer layer of FIG. 3.

FIG. 6 is a cross-sectional view showing another example of the polymer layer of FIG. 3.

FIGS. 7, 8, 9, 10, and 11 are views showing a method of manufacturing the polymer layer of FIG. 3.

FIG. 12 is block-diagram for showing an electronic device according to an embodiment of the disclosure.

FIG. 13 is schematic views for showing the electronic device according to various embodiments of FIG. 12.

### DETAILED DESCRIPTION

Illustrative, non-limiting embodiments will be more clearly understood from the following detailed description in conjunction with the accompanying drawings.

In this specification, a plane may be defined by a first direction D1 and a second direction D2 that intersects the first direction D1. For example, the second direction D2 may be perpendicular to the first direction D1. In addition, a third direction D3 may be a normal direction of the plane. That is, the third direction D3 may be perpendicular to the plane formed by the first direction D1 and the second direction D2.

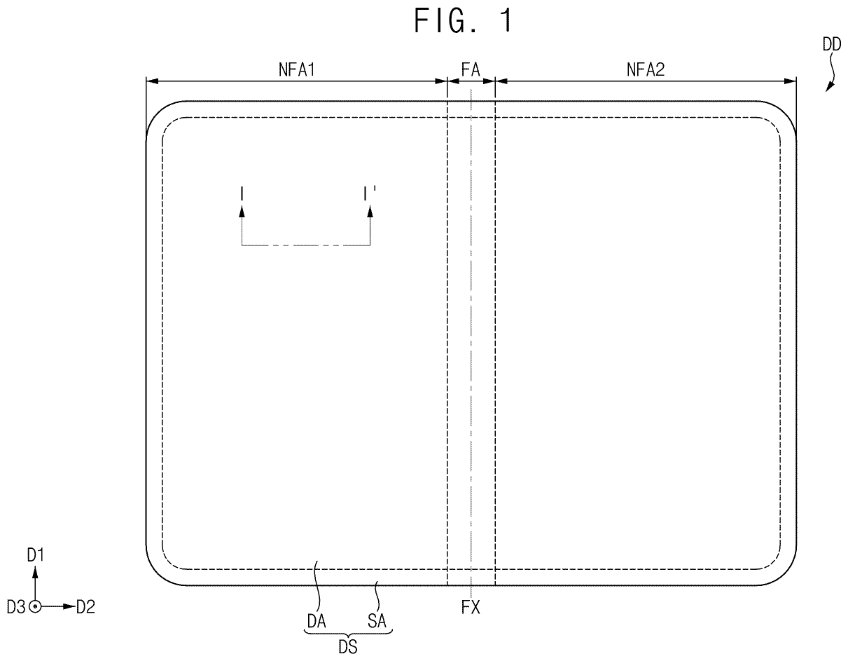

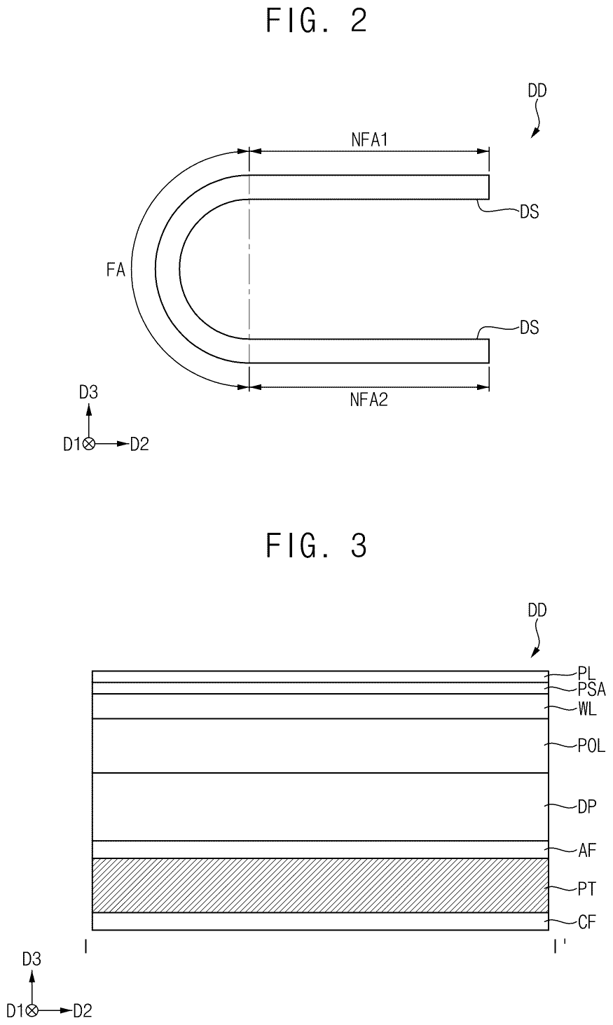

FIG. 1 is a plan view of a display device DD according to an embodiment of the present disclosure. FIG. 2 is a cross-sectional view showing a folded state of the display device DD shown in FIG. 1.

Referring to FIGS. 1 and 2, a top surface of the display device DD may be defined as a display surface DS. The display surface DS may have a plane defined by the first direction D1 and the second direction D2. An image generated by the display device DD may be provided to a user through the display surface DS.

The display surface DS may include a display area DA and a peripheral area SA. The display area DA may display an image, and the peripheral area SA may not display an image. The peripheral area SA may be disposed around the display area DA. For example, the peripheral area SA may surround the display area DA in a plan view.

The display device DD may be a flexible display device. The display device DD may be a foldable display device that is folded or unfolded. The display device DD may include a first area NFA1, a second area NFA2, and a third area FA. The second area NFA2 may be spaced apart from the first area NFA1 in the second direction D2. The third area FA may be disposed between the first area NFA1 and the second area NFA2.

The third area FA may be bent relative to a folding axis FX parallel to the first direction D1, so that the display device DD may be folded. In an embodiment, as shown in FIG. 2, the display device DD may be in-folded so that the display surface DS is not exposed to an outside. That is, when the display device DD is folded, the first area NFA1 and the second area NFA2 of the display surface DS may face each other. In an embodiment, the display device DD may be out-folded so that the display surface DS is exposed to the outside.

The first area NFA1, the second area NFA2, and the third area FA may be referred to as a first non-folding area, a second non-folding area, and a folding area, respectively. Although shown in FIG. 1, the display device DD may include two non-folding areas (the first area NFA1 and the second area NFA2) and one folding area (the third area FA), this is an example and the present disclosure is not necessarily limited thereto. For example, the display device DD may include three or more non-folding areas and two or more folding areas disposed between the non-folding areas.

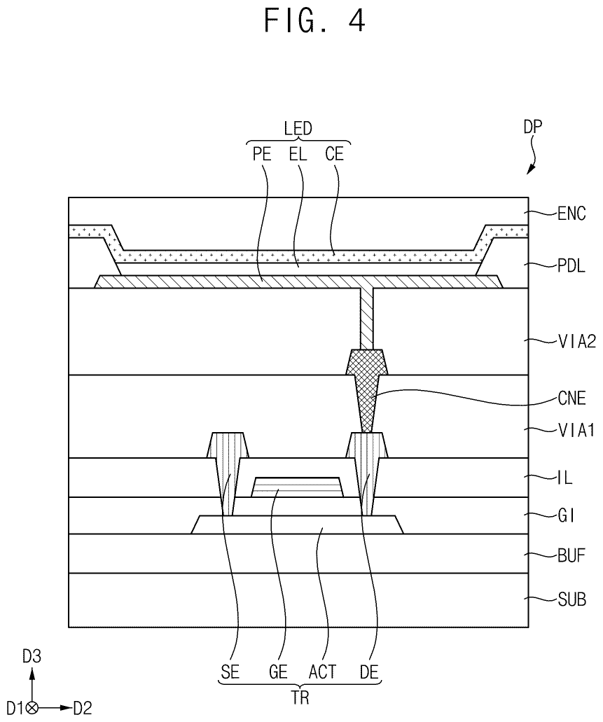

FIG. 3 is a cross-sectional view taken along line I-I′ of FIG. 1.

Referring to FIG. 3, the display device DD may include a cover film CF, a plate PT, an adhesive film AF, a display panel DP, a polymer layer POL, a window layer WL, an adhesive layer PSA, and a protective film PL.

The cover film CF may be disposed on a back of the display device DD. The cover film CF may alleviate external shock to the display device DD. The cover film CF may include at least one of sponge, expanded foam, thermoplastic polyurethane, and polydimethylacrylamide. These may be used alone or in combination with each other. Optionally, the cover film CF may include a light blocking material. Accordingly, the cover film CF may absorb light incident from the back of the display device DD.

The plate PT may be disposed on the cover film CF. The plate PT may prevent the display panel DP from being bent due to external force. That is, the plate PT may maintain the display panel DP in a relatively flat state even when an external force is applied from outside the display device DD. The plate PT may include a rigid or semi-rigid material. For example, the plate PT may include at least one of iron, chromium, carbon, nickel, silicon, manganese, and molybdenum. These may be used alone or in combination with each other. However, embodiments of the present disclosure are not necessarily limited thereto.

The adhesive film AF may be disposed on the plate PT. The adhesive film AF may attach the plate PT and the display panel DP. For example, the adhesive film AF may include at least one of pressure sensitive adhesive (PSA), optical clear adhesive (OCA), and optical clear resin (OCR). However, embodiments of the present disclosure are not necessarily limited thereto.

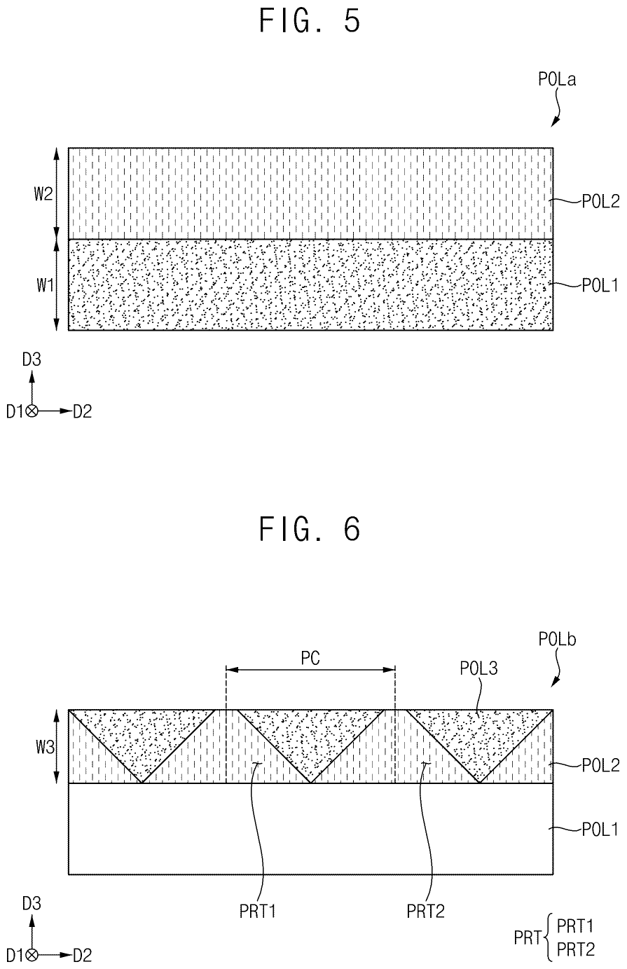

The display panel DP may be disposed on the adhesive film AF. The display panel DP may generate light based on a provided signal. Accordingly, the display panel DP may provide a visual image to a user of the display device DD. The display panel DP will be described in detail later with reference to FIG. 4.

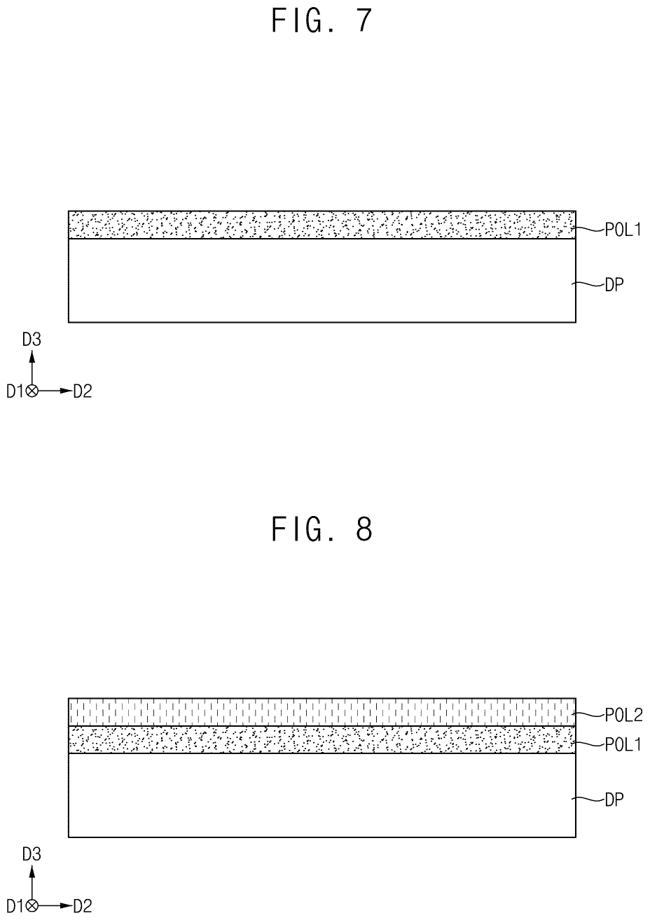

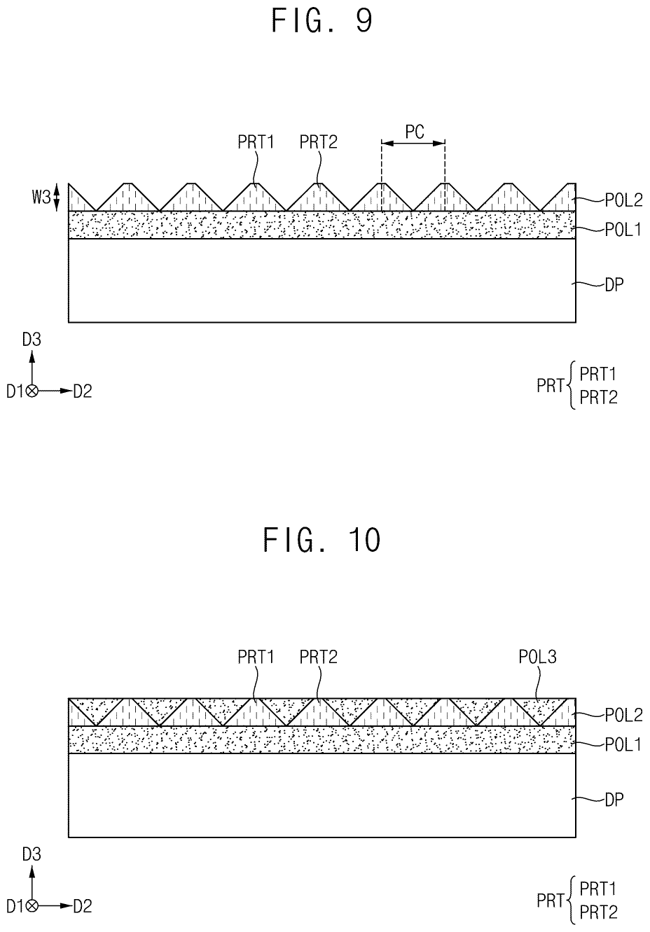

The polymer layer POL may be disposed on the display panel DP. The polymer layer POL may attach the display panel DP and the window layer WL. In addition, the polymer layer POL may support the window layer WL from sagging and protect the display panel DP from external shocks, etc. The polymer layer POL may have a single-layer or multi-layer structure. The polymer layer POL will be described in detail later with reference to FIGS. 5 and 6.

The window layer WL may be disposed on the polymer layer POL. The window layer WL may cover a front surface of the display device DD and protect the display panel DP. The window layer WL may include a substantially transparent material. For example, the window layer WL may be glass or plastic. However, embodiments of the present disclosure are not necessarily limited thereto.

The adhesive layer PSA may be disposed on the window layer WL. The adhesive layer PSA may attach the window layer WL and the protective film PL. The adhesive layer PSA may include a transparent material. For example, the adhesive layer PSA may include at least one of pressure sensitive adhesive (PSA), optical clear adhesive (OCA), and optical clear resin (OCR). However, embodiments of the present disclosure are not necessarily limited thereto.

The protective film PL may be disposed on the adhesive layer PSA. The protective film PL may protect the window layer WL from external impacts and/or scratches. For example, the protective film PL may include a base layer and a hard coating layer. However, embodiments of the present disclosure are not necessarily limited thereto. The protective film PL may further include a low refractive index layer and/or an anti-fingerprint layer.

FIG. 4 is a cross-sectional view showing the display panel DP of FIG. 3.

Referring to FIGS. 1 and 4, the display panel DP may include a substrate SUB, a buffer layer BUF, a gate insulating layer GI, a transistor TR, an interlayer insulating layer IL, a connecting electrode CNE, a first via layer VIA1, a second via layer VIA2, a light emitting diode LED, a pixel defining layer PDL, and an encapsulation layer ENC.

The transistor TR may include an active layer ACT, a gate electrode GE, a source electrode SE, and a drain electrode DE. The light emitting diode LED may include a pixel electrode PE, a light emitting layer EL, and a common electrode CE.

The substrate SUB may include a glass substrate, a metal substrate, a plastic substrate, etc. However, embodiments of the present disclosure are not necessarily limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating into an upper part of the substrate SUB. The buffer layer BUF may include an inorganic insulating material.

The active layer ACT may be disposed on the buffer layer BUF. The active layer ACT may include an oxide semiconductor, a silicon semiconductor, an organic semiconductor, etc. For example, the oxide semiconductor may include at least one oxide from indium (In), gallium (Ga), tin (Sn), zirconium (Zr), vanadium (V), hafnium (Hf), cadmium (Cd), germanium (GE), chromium (Cr), titanium (Ti), and zinc (Zn). The silicon semiconductor may include amorphous silicon, polycrystalline silicon, etc. The active layer ACT may include a source region, a drain region, and a channel region disposed between the source region and the drain region.

The gate insulating layer GI may be disposed on the buffer layer BUF. Specifically, the gate insulating layer GI may cover the active layer ACT on the buffer layer BUF. The gate insulating layer GI may include an inorganic insulating material. In an embodiment, the gate insulating layer GI may be formed entirely in the display area DA and the peripheral area SA.

The gate electrode GE may be disposed on the gate insulating layer GI. The gate electrode GE may at least partially overlap the channel region of the active layer ACT. The gate electrode GE may include a conductive material such as a metal, alloy, conductive metal nitride, conductive metal oxide, or transparent conductive material. Examples of the conductive material that may be used in the gate electrode GE may include gold (Au), silver (Ag), aluminum (Al), platinum (PT), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloy containing aluminum, alloy containing silver, alloy containing copper, alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. In an embodiment, the gate electrode GE may have a single-layer structure or a multi-layer structure including a plurality of conductive layers.

The interlayer insulating layer IL may be disposed on the gate electrode GE. Specifically, the interlayer insulating layer IL may be disposed on the gate insulating layer GI and cover the gate electrode GE on the gate insulating layer GI. The interlayer insulating layer IL may include an inorganic insulating material.

The source electrode SE and the drain electrode DE may be disposed on the interlayer insulating layer IL. Each of the source electrode SE and the drain electrode DE may be connected to the active layer ACT. For example, the source electrode SE may contact the source region of the active layer ACT, and the drain electrode DE may contact the drain region of the active layer ACT. Each of the source electrode SE and the drain electrode DE may include a conductive material. The active layer ACT, the gate electrode GE, the source electrode SE, and the drain electrode DE may form the transistor TR.

The first via layer VIA1 may be disposed on the source electrode SE and the drain electrode DE. Specifically, the first via layer VIA1 may be disposed on the interlayer insulating layer IL and cover the source electrode SE and the drain electrode DE on the interlayer insulating layer IL. The first via layer VIA1 may include an organic insulating material. In an embodiment, the first via layer VIA1 may be formed only in the display area DA and a portion of the peripheral area SA adjacent to the display area DA.

The connection electrode CNE may be disposed on the first via layer VIA1. The connection electrode CNE may transmit a signal transmitted from the transistor TR to the light emitting diode LED. The connection electrode CNE may include metal, alloy, metal nitride, conductive metal oxide, transparent conductive material, etc. These may be used alone or in combination with each other. However, embodiments of the present disclosure are not necessarily limited thereto.

The second via layer VIA2 may be disposed on the connection electrode CNE. Specifically, the second via layer VIA2 may be disposed on the first via layer VIA1 and cover the connection electrode CNE. The second via layer VIA2 may include substantially a same material as the first via layer VIA1.

The pixel electrode PE may be disposed on the second via layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light emitting layer EL may be disposed on the pixel electrode PE. Specifically, the light emitting layer EL may be disposed within an opening defined by the pixel defining layer PDL. That is, the light emitting layer EL may be surrounded by the pixel defining layer PDL. The light emitting layer EL may include at least one of organic light emitting material and/or quantum dots. However, embodiments of the present disclosure are not necessarily limited thereto.

The common electrode CE may be disposed on the light emitting layer EL. The common electrode CE may also be disposed on the pixel defining layer PDL. That is, the common electrode CE may be continuously disposed on the light emitting layer EL and the pixel defining layer PDL.

The common electrode CE may include a conductive material. The light emitting layer EL may emit light based on voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include a cured polymer such as polyacrylate, epoxy resin, or silicone resin. For example, the inorganic encapsulation layer may include silicon oxide, silicon nitride, silicon carbide, aluminum oxide, tantalum oxide, hafnium oxide, zirconium oxide, titanium oxide, etc.

FIG. 5 is a cross-sectional view showing an example of the polymer layer POL of FIG. 3. Referring to FIGS. 3 and 5, the polymer layer POLa may include two different polymers. That is, as shown in FIG. 5, the polymer layer POLa may include a first polymer POL1 and a second polymer POL2. For example, the first polymer POL1 and the second polymer POL2 may include a transparent material to allow light transmitted from the display panel DP to pass through.

The second polymer POL2 may be disposed on the first polymer POL1. That is, the first polymer POL1 may be disposed on the display panel DP, and the second polymer POL2 may be disposed below the window layer WL. Specifically, the first polymer POL1 may be disposed in direct contact with the encapsulation layer (e.g., the encapsulation layer ENC in FIG. 4) of the display panel DP, and the second polymer POL2 may be disposed in direct contact with the window layer WL and the first polymer POL1.

In an embodiment, the first polymer POL1 may have a first modulus, and the second polymer POL2 may have a second modulus less than the first modulus. The modulus of a material, also known as Elastic Modulus or Modulus of Elasticity, is the measurement of a material's elasticity. Elastic modulus quantifies a material's resistance to non-permanent, or elastic, deformation. Since the first polymer POL1 has the first modulus and is disposed at a lower part of the polymer layer POLa, phenomenon of sagging of the window layer WL may be prevented, and a sufficient adhesive force between the display panel DP and polymer layers POLa may be secured. The second polymer POL2 has the second modulus and may be disposed on an upper part of the polymer layer POLa, thereby absorbing and/or dispersing an impact propagated to the display panel DP.

For example, the first modulus of the first polymer POL1 may be about 500 MPa or more and about 2000 MPa or less. Suitably, the first modulus may be about 500 MPa or more and about 1,500 MPa or less. If the first modulus is less than a range described above, the window layer WL may sag. In addition, if the first modulus is greater than the range described above, wrinkles may occur when the display device DD is folded.

The second modulus of the second polymer POL2 may be about 30 MPa or less. If the second modulus is greater than a range described above, an effect of absorbing and/or dispersing an impact propagated to the display panel DP may be reduced, which may cause side effects to the display device DD.

In an embodiment, each of a first thickness W1 of the first polymer POL1 and a second thickness W2 of the second polymer POL2 may be about 30 μm or more and about 70 μm or less. If the first thickness W1 of the first polymer POL1 is less than a range described above, a window sagging phenomenon may occur. When the first thickness W1 of the first polymer POL1 is greater than the range described above, a foldability of the display device DD may be reduced. In addition, when the second thickness W2 of the second polymer POL2 is less than a range described above, a property of the polymer layer POLa to disperse external shocks may be deteriorated. When the second thickness W2 of the second polymer POL2 is greater than the range described above, an adhesive force between the polymer layer POLa and the window layer WL may decrease.

In an embodiment, a sum of the first thickness W1 of the first polymer POL1 and the second thickness W2 of the second polymer POL2 may be about 100 μm or less. When a sum of the first thickness W1 of the first polymer POL1 and the second thickness W2 of the second polymer POL2 is greater than a range described above, a folding property of the display device DD may deteriorate.

In an embodiment, an adhesive force of the first polymer POL1 may be greater than about 1500 gf/inch. Suitably, an adhesive force of the first polymer POL1 may be greater than about 2000 gf/inch. Since an adhesive force of the first polymer POL1 satisfies a range described above, a lifting phenomenon between the first polymer POL1 and the display panel DP may be minimized when a user uses the display device DD.

In an embodiment, an elastic recovery rate of the second polymer POL2 may be about 90% or more. Suitably, an elastic recovery rate of the second polymer POL2 may be about 95% or more. The elastic recovery rate is a measure of how well a material returns to its original shape after being deformed. If an elastic recovery rate of the second polymer POL2 is less than a range described above, a shape of the second polymer POL2 may be deformed when a user uses the display device DD, thereby a peeling phenomenon may occur between the window layer WL and the second polymers POL2.

In an embodiment, a creep value of the second polymer POL2 for about 1 hour may be 10% or less. The creep value is the gradual, permanent deformation of a material under constant stress over a long period. Since the creep value of the second polymer POL2 satisfies a range described above, a shape deformation of the polymer layer POLa may be minimized even if the display device DD is in a folded state.

By disposing a two-layer polymer layer POLa shown in FIG. 5 between the window layer WL and the display panel DP, phenomenon of sagging of the window layer WL may be prevented, and external shocks propagated to the display panel DP may be absorbed and/or dispersed. Accordingly, a stability and reliability of the display device may be improved.

FIG. 6 is a cross-sectional view showing another example of the polymer layer POL of FIG. 3.

Referring to FIGS. 3, 5, and 6, the polymer layer POLb may include the first polymer POL1, the second polymer POL2, and a third polymer POL3.

As shown in FIG. 6, the second polymer POL2 may be disposed on the first polymer POL1, and the third polymer POL3 may be disposed on the second polymer POL2. However, unlike FIG. 5, the second polymer POL2 may have a shape including a plurality of protrusions PRT protruding in the third direction D3 in a cross-sectional view.

Specifically, the second polymer POL2 may have a shape having a plurality of protrusions PRT protruding in the direction of the window layer WL. The second polymer POL2 may include a first protrusion PRT1 and a second protrusion PRT2. The first protrusion PRT1 and the second protrusion PRT2 may be disposed adjacent to each other in the second direction D2.

In an embodiment, each of the protrusions PRT of the second polymer POL2 may have a third thickness W3 in the third direction D3. For example, the third thickness W3 may be about 15 μm or more and about 20 μm or less. However, embodiments of the present disclosure are not necessarily limited thereto.

In an embodiment, each of the protrusions PRT of the second polymer POL2 may be disposed with a constant pitch PC. Specifically, the first protrusion PRT1 and the second protrusion PRT2 may be disposed to be spaced apart from each other by the pitch PC in the second direction D2. That is, a distance between a center of the first protrusion PRT1 and a center of the second protrusion PRT2 in a cross-sectional view may be a distance corresponding to the pitch PC. For example, the pitch PC may be about 10 μm or more and about 50 μm or less. Suitably, the pitch PC may be about 25 μm or more and about 35 μm or less. However, embodiments of the present disclosure are not necessarily limited thereto.

The third polymer POL3 may cover at least a portion of the second polymer POL2. That is, as the second polymer POL2 is disposed on the first polymer POL1, and the third polymer POL3 is disposed on the second polymer POL2, so that the third polymer POL3 may cover at least a portion of the second polymer POL2. As the third polymer POL3 is disposed on the second polymer POL2 to increase a contact area between the window layer WL and the third polymer POL3, so that an adhesive force between the polymer layer POLb and the window between layers WL may be increased.

For example, at least a portion of the second polymer POL2 may be exposed without being covered by the third polymer POL3. That is, when the polymer layer POLb and the window layer WL are attached, the second polymer POL2 and the window layer WL may directly contact each other. As the second polymer POL2 is not completely covered by the third polymer POL3 and is partially exposed, the second polymer POL2 may directly contact the window layer WL and may disperse a shock transmitted to the display panel DP.

In an embodiment, the third polymer POL3 may include a same material as the first polymer POL1. That is, the third polymer POL3 may have the first modulus as the first polymer POL1.

As a result, the first polymer POL1 having the first modulus, the second polymer POL2 having the second modulus, and the third polymer POL3 having the first modulus may be sequentially disposed on the display device DD. As first polymer POL1 and the third polymer POL3 directly contact the display panel DP and the window layer WL respectively, an adhesive force may be improved. In addition, as the second polymer POL2 is in direct contact with the window layer WL and is disposed on an upper portion of the polymer layer POLb, the polymer layer POLb may absorb and/or disperse an impact transmitted to the display panel DP. Accordingly, stability and reliability of the display device DD may be improved.

In addition, by placing the polymer layers (POLa, POLb) having a plurality of layers in direct contact with the window layer WL and the display panel DP, a damping layer and an adhesive process for attaching the damping layer may be omitted, and an overall thickness of the display device DD may be thinner. That is, as the damping layer and the adhesive process for attaching the damping layer are omitted, thereby reducing a process cost of the display device DD.

TABLE 1

| | | | Elastic | | Adhesive |
|---|---|---|---|---|---|
| | | | recovery | | force(gf/ |
| type | material | modulus(MPa) | rate(%) | creep(%) | inch) |
| low | LM1 | 5.2 | 97.4 | 0 | 830 |
| modulus | LM2 | 8.5 | 97 | 0 | 1002 |
| | LM3 | 16.1 | 95.1 | 0 | 1045 |
| | LM4 | 48.8 | 90.2 | 4 | 997 |
| high | HM1 | 550 | 87.9 | 22 | 1563 |
| modulus | HM2 | 1000 | 85 | 28 | 2010 |
| | HM3 | 1430 | 83.4 | 33 | 2007 |
| | HM4 | 2780 | 68.4 | 40 | 2500 |

Referring to Table 1, modulus, elastic recovery rate, creep, and adhesive force of each of low modulus material and high modulus material can be confirmed.

The low modulus material may correspond to the second polymer POL2 in FIGS. 5 and 6. Likewise, the high modulus material may correspond to the first polymer POL1 and the third polymer POL3 in FIGS. 5 and 6.

TABLE 2

| | | | Pen-drop |
|---|---|---|---|
| | low modulus | high modulus | height(cm) |
| Comparative | X | ◯ | 9-10 |
| Example | | | |
| Example 1 | LM1 | HM1 | 13 |
| Example 2 | LM2 | HM2 | 12-13 |
| Example 3 | LM2 | HM2 | 12 |
| Example 4 | LM3 | HM3 | 11-12 |
| Example 5 | LM3 | HM3 | 10-11 |
| Example 6 | LM4 | HM4 | 8-9 |

Referring to Table 2 and FIGS. 3, 5, and 6, in Examples 1 to 6, the low modulus material and the high modulus material described in Table 1 were laminated as shown in FIGS. 5 and 6. The low modulus material was laminated to have a thickness of 60 μm, and the high modulus material was laminated to have a thickness of 40 μm. That is, the polymer layer POL was laminated so that the overall thickness was 100 μm. Afterwards, a pen-drop experiment was performed on the polymer layer POL. The pen-drop experiment is an experiment in which a pen weighing about 5.6 g is freely dropped from a certain height to check whether a material is destroyed.

Before carrying out Examples 1 to 6, a comparative example was carried out where the polymer layer POL was composed of a single layer including only the high modulus materials shown in Table 1. According to the comparative example, when composed of a single layer containing only one of the high modulus materials in Table 1, it can be confirmed that the polymer layer POL is destroyed in a pen-drop test between about 9 cm or more and about 10 cm or less.

In Example 1, when the low modulus material was laminated with LM1 and the high modulus material was laminated with HM1, it can be confirmed that the polymer layer (POL) was destroyed at about 13 cm in a pen-drop experiment.

In Example 2, when the low modulus material was laminated with LM2 and the high modulus material was laminated with HM2, it can be confirmed that the polymer layer (POL) was destroyed in a pen-drop experiment between about 12 cm and about 13 cm.

In Example 3, when the low modulus material was laminated with LM2, the high modulus material was laminated with HM2, and the protrusions were patterned as shown in FIG. 6, it can be confirmed that the polymer layer (POL) was destroyed at about 12 cm in the pen-drop test.

In Example 4, when the low modulus material was laminated with LM3 and the high modulus material was laminated with HM3, it can be confirmed that the polymer layer (POL) was destroyed at a height of about 11 cm to about 12 cm in a pen-drop experiment.

In Example 5, when the low modulus material was laminated with LM3, the high modulus material was laminated with HM3, and the protrusions were patterned as shown in FIG. 6, it can be confirmed that the polymer layer (POL) were destroyed.

In Example 6, when the low modulus material was laminated with LM4 and the high modulus material was laminated with HM4, it can be confirmed that the polymer layer (POL) was destroyed at a height of about 8 cm to about 9 cm in a pen-drop experiment.

As a result, it can be confirmed that an impact resistance was further improved in Examples 1 to 5 compared to the comparative example, and in Example 6, it can be confirmed that an impact resistance was not improved. Accordingly, as described with reference to FIGS. 5 and 6, when the polymer layer POL satisfies Examples 1 to 5 of Table 2, it can be confirmed that an impact resistance of the polymer layer POL is improved. In other words, when numerical ranges of the first polymer POL1, the second polymer POL2, and the third polymer POL3 described with reference to FIGS. 5 and 6 are satisfied (e.g., the first modulus of the polymer POL1 is about 500 MPa or more and about 2000 MPa or less), it can be confirmed that an impact resistance of the polymer layer POL is improved.

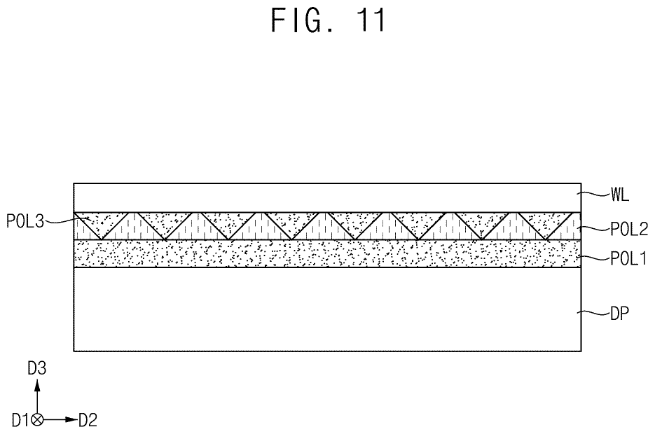

FIGS. 7, 8, 9, 10, and 11 are views showing a method of manufacturing the polymer layer of FIG. 3.

Referring to FIG. 7, the first polymer POL1 having the first modulus may be formed on the display panel DP. Specifically, the first polymer POL1 may be formed on the display panel DP through inkjet coating, spray coating, stain coating, slit coating, etc.

After forming the first polymer POL1 on the display panel DP, the first polymer POL1 may be cured. The first polymer POL1 may be cured on the display panel DP through thermal curing, UV curing, etc. However, embodiments of the present disclosure are not necessarily limited thereto.

Referring further to FIG. 8, the second polymer POL2 having the second modulus may be formed on the first polymer POL1. The second modulus may be smaller than the first modulus. Like the first polymer POL1, the second polymer POL2 may be formed through inkjet coating, spray coating, stain coating, slit coating, etc.

After forming the second polymer POL2 on the first polymer POL1, the second polymer POL2 may be cured. The second polymer POL2 may be cured on the first polymer POL1 through heat curing, UV curing, etc. However, embodiments of the present disclosure are not necessarily limited thereto.

As the first polymer POL1 and the second polymer POL2 shown in FIGS. 7 and 8 are sequentially formed, the polymer layer POLa shown in FIG. 5 may be formed.

Referring further to FIG. 9, after curing the second polymer POL2, as at least a portion of the second polymer POL2 is etched, the second polymer POL2 may be formed to have a protruding pattern including a plurality of protruding protrusions PRT in the third direction D3 in a cross-sectional view. The protrusions PRT of the second polymer POL2 may be formed using a laser, etc.

The protrusions PRT may have the constant pitch PC. For example, the first protrusion PRT1 and the second protrusion PRT2 may be spaced apart from each other with the pitch PC in the second direction D2. Specifically, a center of the first protrusion PRT1 and a center of the second protrusion PRT2 may be spaced apart by the pitch PC distance. The pitch PC may be about 10 μm or more and about 50 μm or less. Suitably, the pitch PC may be about 25 μm or more and about 35 μm or less.

In addition, each of the protrusions PRT may have the constant third thickness W3 in the third direction D3. For example, the third thickness W3 may be about 15 μm or more and about 20 μm or less.

Referring further to FIGS. 10 and 11, the third polymer POL3 may be formed on the protrusions PRT of the second polymer POL2. Specifically, the third polymer POL3 may be sprayed between the protrusions PRT of the second polymer POL2 to cover at least a portion of the second polymer POL2. For example, the third polymer POL3 may not completely cover the second polymer POL2 and may expose a top surface of the second polymer POL2. Since at least a portion of the second polymer POL2 is exposed, the window layer WL may be in directly contact with the second polymer POL2.

The third polymer POL3 may include a same material as the first polymer POL1.

That is, the third polymer POL3 may have the first modulus. As the third polymer POL3 directly contacts the window layer (e.g., the window layer WL in FIG. 3), an adhesive force between the polymer layer POL and the window layer WL may be improved.

As a result, the display device DD shown in FIG. 3 may be manufactured through the method of manufacturing of FIGS. 7 to 11.

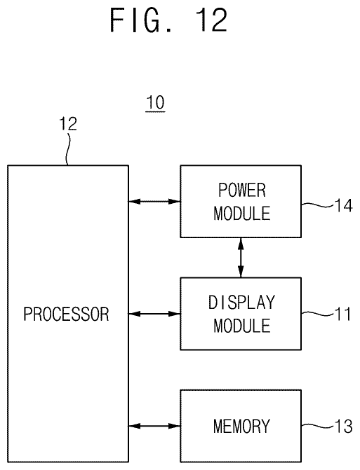

FIG. 12 is block-diagram for showing an electronic device according to an embodiment of the disclosure.

Referring to FIG. 1 and FIG. 12, the display device DD according to the embodiments of present disclosure may be applied to various electronic devices 10. The electronic device 10 according to an embodiment may include the display device DD, and may further include a module or device including additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate power necessary for an operation of the electronic device 10.

At least one of the components of the electronic device 10 described above may be included in the display device according to the embodiments described above. In addition, some of individual modules functionally included in one module may be included in the display device, and other parts may be provided separately from the display device. For example, the display device DD may include the display module 11, and the processor 12, the memory 13, and the power module 14 may be provided in the form of other devices within the electronic device 10 other than the display device DD.

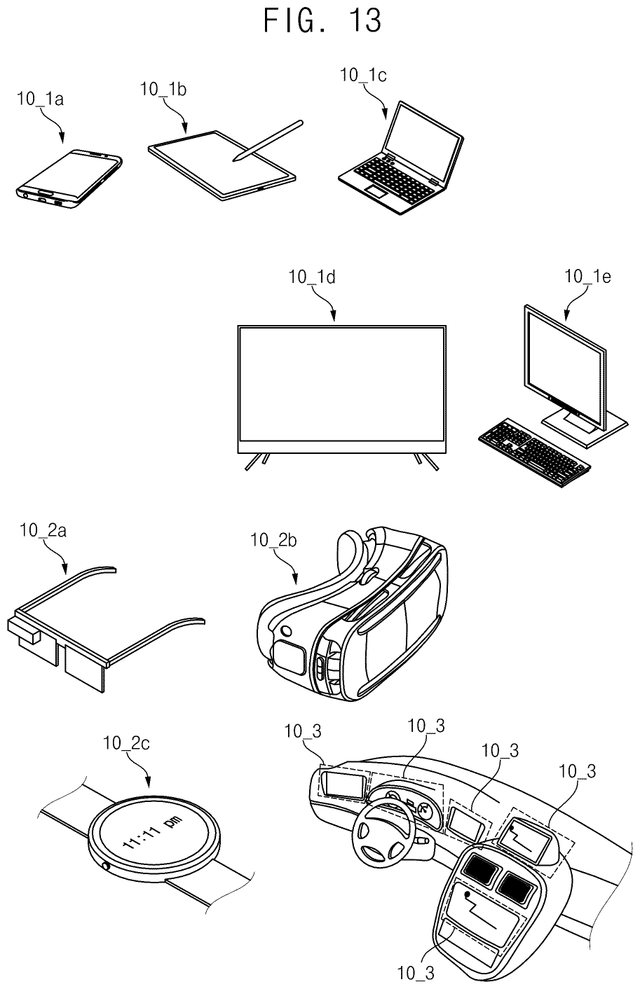

FIG. 13 is schematic views for showing the electronic device according to various embodiments of FIG. 12.

Referring to FIG. 12 and FIG. 13, various electronic devices to which the display device DD according to embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (center information display) and a room mirror display placed on a dashboard, center fascia, or dashboard of an automobile.

However, this is exemplary, and the electronic device 10 according to embodiments of the present disclosure is not limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

The present disclosure may be applied to the display device and the electronic device including a same. For example, the present disclosure may be applied to high-resolution smartphones, mobile phones, smart pads, smart watches, tablet PCs, vehicle navigation systems, televisions, computer monitors, laptops, etc.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a display panel;
a first polymer disposed on the display panel, in direct contact with the display panel, and having a first modulus;
a second polymer disposed on the first polymer, in direct contact with the first polymer, and having a second modulus less than the first modulus; and
a window layer disposed on the second polymer.

2. The display device of claim 1, wherein the first modulus is about 500 MPa or more and about 2000 MPa or less.

3. The display device of claim 1, wherein the second modulus is about 30 MPa or less.

4. The display device of claim 1, wherein a thickness of each of the first polymer and the second polymer is about 30 μm or more and about 70 μm or less.

5. The display device of claim 1, wherein a sum of a thicknesses of the first polymer and the second polymer is about 100 μm or less.

6. The display device of claim 1, wherein an adhesive force of the first polymer is greater than an adhesive force of the second polymer.

7. The display device of claim 1, wherein an adhesive force between the first polymer and the display panel is about 1500 gf/inch or more.

8. The display device of claim 1, wherein an elastic recovery rate of the second polymer is about 90% or more.

9. The display device of claim 1, wherein a creep value of the second polymer for about 1 hour is about 10% or less.

10. The display device of claim 1, wherein the first polymer and the second polymer are transparent.

11. The display device of claim 10, further comprising:
a third polymer disposed on the second polymer and covering at least a portion of the second polymer, and
wherein the second polymer has a shape including a plurality of protrusions protruding in a direction of the window layer in a cross-sectional view.

12. The display device of claim 11, wherein the protrusions of the second polymer are in direct contact with the window layer.

13. The display device of claim 11, wherein the first polymer and the third polymer include a same material.

14. The display device of claim 11, wherein a thickness of each of the protrusions of the second polymer is about 15 μm or more and about 20 μm or less.

15. The display device of claim 11, wherein the protrusions of the second polymer have a constant pitch, and
wherein the pitch is about 10 μm or more and about 50 μm or less.

16. A method of manufacturing a display device comprising:
providing a display panel;
forming a first polymer having a first modulus on the display panel;
forming a second polymer having a second modulus less than the first modulus on the first polymer; and
forming a window layer on the second polymer.

17. The method of claim 16, further comprising:
forming a protrusion pattern including a plurality of protrusions in the second polymer.

18. The method of claim 17, further comprising:
forming a third polymer covering at least a portion of the second polymer on the second polymer.

19. The method of claim 17, wherein a thickness of each of the protrusions of the second polymer is about 15 μm or more and about 20 μm or less.

20. The method of claim 17, wherein the protrusions of the second polymer have a constant pitch, and
wherein the pitch is about 10 μm or more and about 50 μm or less.

21. An electronic device comprising:
a display device; and
a processor that drives the display device, and
wherein the display device includes:
a display panel;
a first polymer disposed on the display panel, in direct contact with the display panel, and having a first modulus;
a second polymer disposed on the first polymer, in direct contact with the first polymer, and having a second modulus less than the first modulus; and
a window layer disposed on the second polymer.
